(19) United States
(12) Patent Application Publication
(10) Pub. No.: US 2011/0220970 A1
(43) Pub. Date: Sep. 15, 2011

(54) SOLID STATE IMAGING DEVICE

(75) Inventors: Akira KOMATSU, Kanagawa-ken (JP); Hitoshi Tsuji, Kanagawa-ken (JP); Kaori Fuse, Kanagawa-ken (JP); Kazuyuki Saito, Kanagawa-ken (JP)

(73) Assignee: KABUSHIKI KAISHA TOSHIBA, Tokyo (JP)

(21) Appl. No.: 12/955,376

(22) Filed: Nov. 29, 2010

(30) Foreign Application Priority Data
Mar. 10, 2010 (JP) 2010-052450

(51) Int. Cl. H01L 27/148

(52) U.S. Cl. 257/228

(57) ABSTRACT

In one embodiment, a semiconductor substrate has first and second principal surfaces opposite to each other, and has a penetration hole extending from the first principal surface to the second principal surface. An imaging element portion is formed on the first principal surface side. A first insulating film is formed on the first principal surface side. An interconnection electrode is formed in the first insulating film and connected to the imaging element portion. A second insulating film is provided to cover a surface of the penetration hole and the second principal surface except at least a portion facing the interconnection electrode. The second insulating film contains particles and is configured to intercept an infrared ray and to transmit a visible light. A conductor film contacts the interconnection electrode and is formed on the second insulating film.

### CROSS-REFERENCE TO RELATED APPLICATION(S)

This application is based upon and claims the benefit of priority from the prior Japanese Patent Application No. 2010-52450, filed on Mar. 10, 2010, the entire contents of which are incorporated herein by reference.

### FIELD

Embodiments described herein relate generally to a solid state imaging device.

### BACKGROUND

A solid state imaging device such as a CCD (Charge Coupled Device) or a CMOS sensor (Complementary Metal Oxide Semiconductor Sensor) is provided with a solid state imaging element. The solid state imaging device is widely used for a cellular phone, a camera, a video camera or a personal computer. With miniaturization and high functionalization of these electronic equipments, miniaturization and high performance have been required with respect to the solid state imaging device.

In a solid state imaging device, in order to promote miniaturization, a penetration electrode may be provided in a semiconductor substrate in which a solid state imaging element is formed. The penetration electrode connects a principal surface of the semiconductor substrate, in which the solid state imaging element is formed, with a back-surface on its opposite side, electrically. An interconnection is led out from the principal surface to the back-surface.

A first electrode is formed on the semiconductor substrate on the back-surface side, and a second electrode is formed on a mount substrate. A solder ball connects the first electrode with the second electrode directly. A silicon substrate may be used as the semiconductor substrate.

The thickness of the semiconductor substrate is thinly formed to be about 100 μm in many cases, in consideration of the throughput at the time of forming the penetration electrode. As the semiconductor substrate becomes thinner, the quantity of infrared light incident into the solid state imaging element from the back-surface increases more so that the problem of causing photographing in the element occurs.

JP 2009-99591A discloses a solid state imaging device provided with a light intercepting layer on a back-side surface of a semiconductor substrate in which a solid state imaging element is formed. In the light intercepting layer, particles of a material such as carbon or pigment are distributed.

The light intercepting layer of the solid state imaging device presents an effect of intercepting visible light as well as an effect of intercepting incident infrared light from the back-side surface. Therefore, as the light intercepting layer is thickened more so as to enhance the effect of intercepting infrared light, the effect of intercepting visible light increases more. As a result, the alignment between the semiconductor substrate and a transfer mask using visible light can not be ensured so that the manufacturing yield may be reduced.

### BRIEF DESCRIPTION OF THE DRAWINGS

FIG. 1 is a sectional view schematically showing a configuration of a camera module incorporating a solid state imaging device according to a first embodiment.

FIG. 2 is a sectional view schematically showing a mount substrate and a portion of the solid state imaging device according to the first embodiment which is surrounded by a dashed ellipse shown in FIG. 1, and is also an enlarged and concrete view of the portion of the device.

FIG. 3 is a sectional view schematically showing a detailed structure of an insulating film which intercepts an infrared ray.

FIGS. 4A to 4F are sectional views schematically showing manufacturing steps of the solid state imaging device according to the first embodiment.

FIG. 5 shows wavelength dependent characteristics of light transmission rates of insulating films and a semiconductor substrate.

FIG. 6 is a sectional view schematically showing a portion of the solid state imaging device according to a modification of the first embodiment which corresponds to the portion of the device surrounded by the dashed ellipse shown in FIG. 1, and is also an enlarged and concrete view of the portion.

FIG. 7A is a sectional view showing a portion of the solid state imaging device according to a second embodiment which corresponds to the portion of the device surrounded by the dashed ellipse shown in FIG. 1, and is also an enlarged and concrete view of the portion.

FIG. 7B is a sectional view of an insulating film which intercepts an infrared ray.

FIG. 8 is a sectional view schematically showing a portion of the solid state imaging device according to a third embodiment which corresponds to the portion of the device surrounded by the dashed ellipse shown in FIG. 1, and is also an enlarged and concrete view of the portion.

### DETAILED DESCRIPTION

According to one embodiment, a solid state imaging device having a semiconductor substrate is provided. The semiconductor substrate has first and second principal surfaces opposite to each other. The semiconductor substrate has a penetration hole extending from the first principal surface to the second principal surface. An imaging element portion is formed on the first principal surface side. A first insulating film is formed on the first principal surface side.

An interconnection electrode is formed in the first insulating film and connected to the imaging element portion. A second insulating film is provided to cover the surface of the penetration hole and the second principal surface except at least a portion facing the interconnection electrode. The second insulating film contains particles and is configured to intercept an infrared ray and to transmit a visible light. A conductor film contacts the interconnection electrode and is formed on the second insulating film. The conductor film is led out on a side of the second principal surface.

According to another embodiment, a solid state imaging device having a semiconductor substrate is provided. The semiconductor substrate has first and second principal surfaces opposite to each other. The semiconductor substrate has a penetration hole extending from the first principal surface to the second principal surface. An imaging element portion is formed on the first principal surface side. A first insulating film is formed on the first principal surface side.

An interconnection electrode is formed in the first insulating film and connected to the imaging element portion. A second insulating film is provided to cover a surface of the penetration hole and the second principal surface except at least a portion facing the interconnection electrode. A conductor film is formed to cover the second insulating film and to contact the interconnection electrode and to be led out on a side of the second principal surface. A third insulating film covers the conductor film. The third insulating film is configured to intercept an infrared ray and to transmit a visible light.

Hereinafter further embodiments will be described with reference to the drawings. In the drawings, the same numerals denote the same or similar portions respectively.

In the following, a surface of a semiconductor substrate existing on a side where an imaging element is formed is mentioned as “a principal surface”, simply, or “a first principal surface”, and a surface of the semiconductor substrate existing on the opposite side is mentioned as “a back surface” or “a second principal surface”.

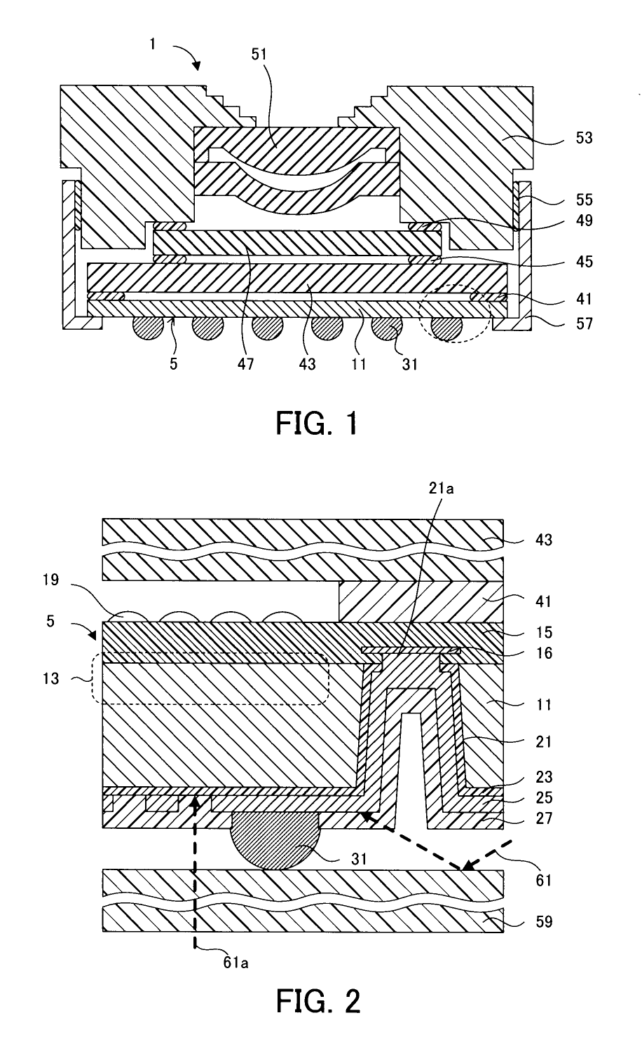

A solid state imaging device according to a first embodiment will be described with reference to FIGS. 1 to 3.

FIG. 1 is a sectional view schematically showing a configuration of a camera module incorporating the solid state imaging device according to the first embodiment.

As shown in FIG. 1, a camera module 1 is provided with a solid state imaging device 5, a glass substrate 43, a light filter 47 and an optical lens 51. These components are disposed like layers without direct contact with each other. These components are arranged in an order along an optical axis from the bottom to the top of the figure. The solid state imaging device 5 has an imaging element formed in a wafer-shaped semiconductor substrate 11 of silicon.

The optical lens 51 is fixed to a lens holder 53 which is made of a light intercepting material. Adhesion materials 41, 45 and 49 fix the solid state imaging device 5, the glass substrate 43, the light filter 47 and the lens holder 53 respectively in this order. A light intercepting plate 57 is fixed to a side surface of the lens holder 53 via an adhesion material 55.

The light intercepting plate 57 covers side surfaces of the solid state imaging device 5, the glass substrate 43 and the light filter 47. The light intercepting plate 57 intercepts unnecessary light which enters into the solid state imaging device 5 from the side surfaces. Infrared light unnecessary for imaging proceeds to enter from a side of an object to be photographed. The light filter 47 has an effect of intercepting the infrared light unnecessary for imaging. The solid imaging device 5 has plural solder balls 31 disposed in array as external terminals. The solder balls 31 are formed on the back surface, i.e., on a surface on a lower side of the semiconductor substrate 11.

FIG. 2 is an enlarged and concrete view of a portion of the solid state imaging device 5 surrounded by a dashed ellipse shown in FIG. 1.

As shown in FIG. 2, the solid state imaging device 5 is provided with an imaging element portion 13, an interconnection electrode 16, an insulating film 23 for intercepting infrared ray, a conductor film 25 and the solder balls 31. The imaging element portion 13 is formed in a surface region extending downward from the first principal surface of the semiconductor substrate 11. The interconnection electrode 16 is formed in an interlayer insulating film 15 in proximity to the first principal surface.

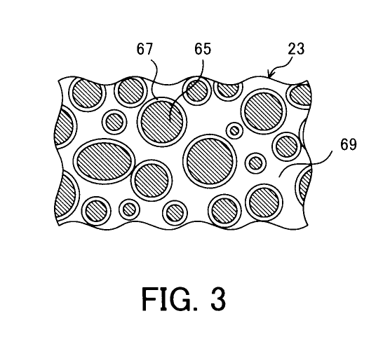

The insulating film 23 covers an inner surface of a penetration hole 21 and the second principal surface. The penetration hole 21 extends from the first principal surface to the second principal surface of the semiconductor substrate 11. The insulating film 23 contains particles 65 shown in FIG. 3 to intercept infrared light, which will be explained in detail below. The conductor film 25 is connected to the interconnection electrode 16, and is led out to the second principal surface on the lower side along the insulating film 23. The solder balls 31 are connected to the conductor film 25 formed on the second principal surface.

The imaging element portion 13 includes CMOS sensors, for example. The imaging element portion 13 is formed in the surface region of the semiconductor substrate 11 by a well-known manufacturing process. The imaging element portion 13 is connected to the interconnection electrode 16. On the interlayer insulating film 15, micro lenses 19 are formed. The micro lenses 19 introduce incidence light for imaging to the imaging element portion 13 efficiently.

The penetration hole 21 of the semiconductor substrate 11 has a taper shape. The opening diameter of the taper shape is large on the lower side and small on the upper side. The penetration hole 21 penetrates the semiconductor substrate 11 in an up and down direction, and reaches the interlayer insulating film 15. An upper end of the insulating film 23 is projected to an inside of the penetration hole 21 in an opening diameter direction in order to form a projection portion. By the projection portion, the insulating film 23 contacts the interlayer insulating film 15 more certainly. When the thickness of the insulating film 23 is large enough, the projection portion is not always formed.

As shown in FIG. 3, the insulating film 23 is made by distributing particles 65 in a resin 69 such as polyimide. The particles 65 have a characteristic of reflecting infrared ray, and are covered with insulating films 67 respectively. The particles 65 may be an oxide such as a SnO₂—Sb₂O₃ series oxide (antimony doped tin oxide) or an In₂O₃—SnO₂ series oxide (tin doped indium oxide).

The particles 65 have a spherical or oval-spherical shape, and have an average particle diameter of about 20 nm. The insulating films 67 are a silicon oxide film, for example. The insulating films 67 coat the particles 65 so as to avoid direct contact of the particles with each other. The particles 65 have large and small particle diameters so far as they are shown in the sectional view of FIG. 3, but the actual particle diameters are close to each other. The average particle diameter of the particles 65 is preferably about a quarter wave length of a visible light, for example, 100 nm or less, in order to suppress the influence of dispersion. Especially, the average particle diameter of the particles 65 needs to be 10 to 50 nm in order to obtain a sufficient infrared intercepting effect by using the particles 65.

Return to FIG. 2, the conductor film 25 is formed so as to cover a portion of the insulating film 23 existing in the penetration hole 21. The conductor film 25 is extended along an inner surface of the insulating film 23 in a direction (an up and down direction in FIG. 2) in which the penetration hole 21 extends. The conductor film 25 is extended via a concave hole 21a provided in the interlayer insulating film 15 to the interconnection electrode 16.

A portion of the conductor film 25 is patterned on the side of the second principal surface of the semiconductor substrate 11 to form an interconnection electrode. The interconnection electrode is connected to the conductor film 25 and is led out to the lower surface of the semiconductor substrate 11. The conductor film 25 may be composed of a seed layer of titanium (Ti) or copper (Cu) and a metal film of copper, for example, which is coated on the seed layer by plating.

The insulating film 23 and the conductor film 25 are covered by a solder resist film 27. Openings are opened at portions of the solder resist film 27 on the second principal surface film 27. In the openings, the solder balls 31 to be connected to the conductor film 25 are provided respectively. The solder balls 31 are also connected with electrodes (not illustrated) of a mount substrate 59, when the solid state imaging device 5 is used as electronic equipment.

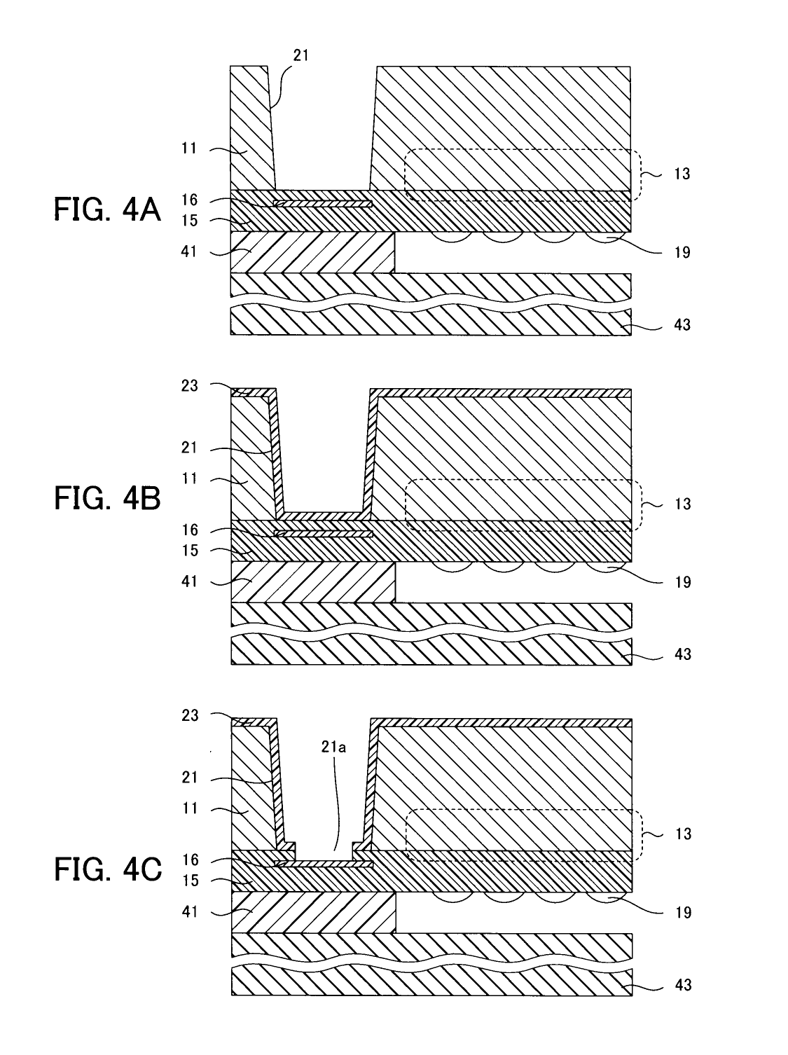

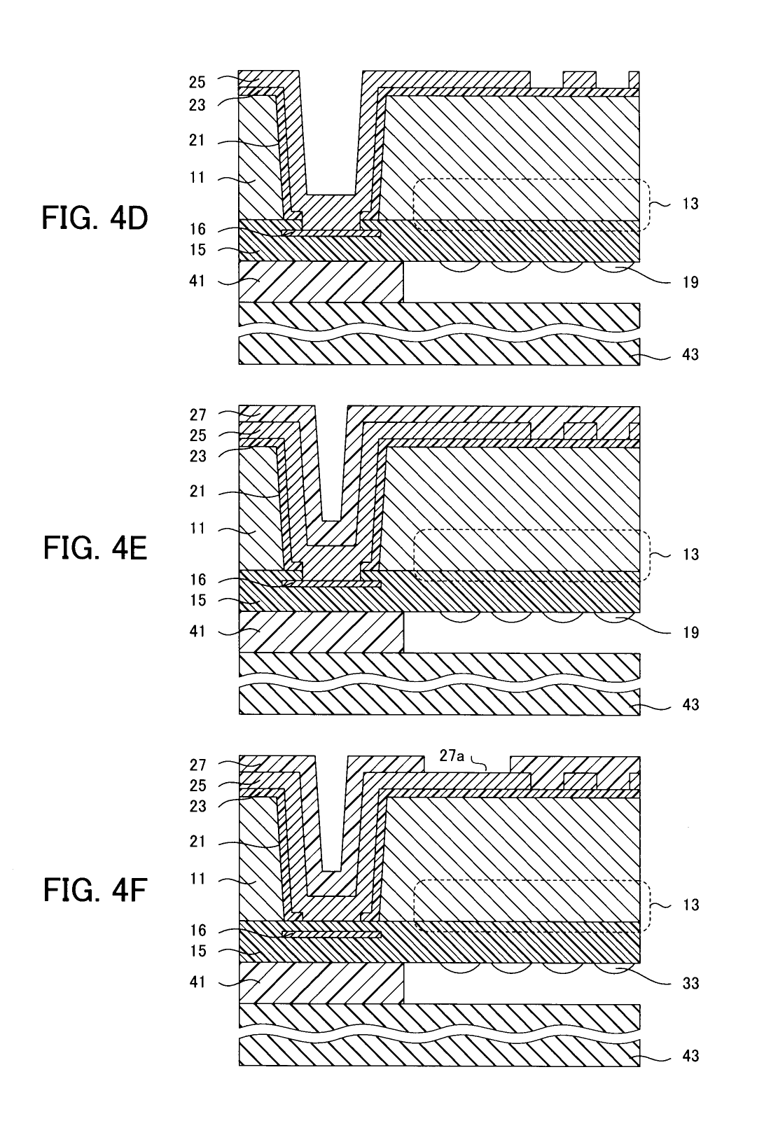

A method of manufacturing the solid state imaging device 5 will be described with reference to the sectional views shown in FIGS. 4A to 4F. FIGS. 4A to 4F show areas corresponding to the sectional view shown in FIG. 2, respectively. FIGS. 4A to 4F have a relation that FIGS. 4A to 4F are obtained by rotating the sectional view of FIG. 2 by 180 degrees.

As shown in FIG. 4A, a flat semiconductor substrate 11 is provided with an imaging element portion 13, an interlayer insulating film 15, an interconnection electrode 16 and micro lenses 19. The semiconductor substrate 11 is fixedly attached to a glass substrate 43 via an adhesion material 41 provided on the interlayer insulating film 15. The adhesion material 41 does not intercept the optical way for imaging which extends to the imaging element portion 13.

The semiconductor substrate 11 is wafer-shaped. A back-side surface (an upper-side surface in FIG. 4A) of the semiconductor substrate 11 is thinned by a method such as a back-grinding method until it becomes about 100 μm in thickness. The back side surface of the semiconductor substrate 11 is flattened so that grinding traces may not remain.

On the back-side surface of the semiconductor substrate 11, a resist film (not illustrated) is formed via an oxide film, for example. The resist film is patterned by a selective exposure and a selective etching so as to correspond to an opening of a penetration hole 21 to be formed.

The penetration hole 21 is formed in the flat semiconductor substrate 11 to extend from the back-side surface. The penetration hole 21 is formed using the patterned resist film as a mask, by a RIE (Reactive Ion Etching) method. For the selective exposure of the patterned resist film, an apparatus such as a double-sided aligner or a double-sided stepper is employed. In the apparatus, an infrared light is radiated from the back surface side via the substrate 11 to the principal surface side.

Using the infrared light, alignment of a glass mask (not shown) is performed to an alignment mark (not shown) which is provided on the principal surface side (a lower side in FIG. 4A) of the semiconductor substrate 11. The glass mask is arranged on the back surface side and has a pattern corresponding to the opening,

Desirably, the penetration hole 21 is formed in such a tapered shape as the hole 21 becomes narrower gradually as the penetration hole 21 extends in a direction of the interlayer insulating film 15. The hole 21 becomes narrower gradually as the penetration hole 21 extends from the opening formed on the back surface side of the semiconductor substrate 11. The resist film is removed after forming the penetration hole 21, and a residual substance produced by the RIE is removed if necessary.

As shown in FIG. 4B, an insulating film 23 for intercepting an infrared ray is formed on the back-side surface of the semiconductor substrate 11 and on a surface of the penetration hole 21, by an applying method. The applying method can be selected from a spinner method, an ink-jet method, a dispenser method, etc. The insulating material of the insulating film 23 is composed of a resin 69 such as polyimide and particles 65 for intercepting infrared ray which are contained in the resin 69, as shown in FIG. 3. Accordingly, in manufacturing, the insulating material of the insulating film 23 may be dissolved by a solvent and be applied onto the semiconductor substrate 11, as the case where a pure polyimide is applied.

The solvent volatilizes by calcination finally, and an insulating film 23 with the particles 65 distributed in the resin 69 is obtained. The quantity of the particles 65 to be distributed and the film thickness of the insulating film 23 to be applied are arranged according to the transmission rate of an infrared ray to be intercepted.

As shown in FIG. 4C, a resist film (not illustrated) is newly formed on the insulating film 23 via an oxide film, and is patterned. Holes are opened in a portion of the insulating film 23 in contact with the interlayer insulating film 15 and in a portion of the interlayer insulating film 15, by a RIE method using the patterned resist film as a mask. The interconnection electrode 16 is exposed to the side of the penetration hole 21 via the holes. By this step, a projection portion of the insulating film 23 is formed to project along the interlayer insulating film 15 to the inside of the opening of the penetration hole 21. After forming the holes, the resist film is removed, and a residual substance produced by the RIE is removed depending on necessity.

In stead of the above method where the holes are formed using the patterned resist film as a mask, the following method may be employed. In the method, a photosensitive resin is used as the resin 69 constituting the insulating film 23. The insulating film 23 is patterned, and a hole is opened in the interlayer insulating film 15 by using the patterned insulating film as a mask.

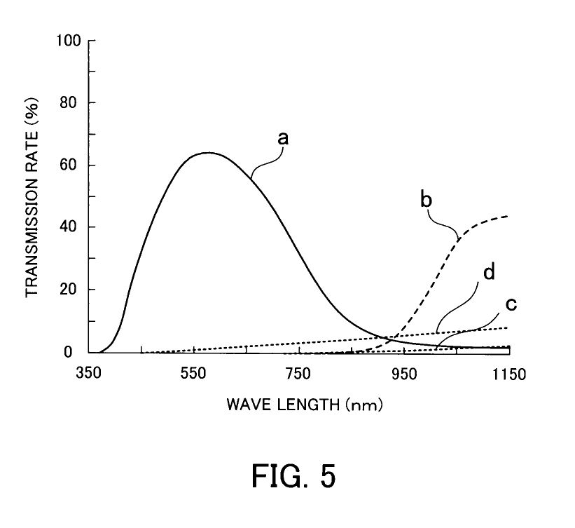

FIG. 5 shows characteristics of light transmission rate which depend on kinds of films. A curve “a” shows a characteristic of the insulating film 23 for intercepting infrared ray with a 2-3 μm thickness. A curve “b” shows a characteristic of the semiconductor substrate having a 50-100 μm thickness. A curve “c” shows a characteristic of a black-color insulating film having a 3-4 μm thickness. A curve “d” shows a characteristic of a thin black-color insulating film having a 2-3 μm thickness.

The insulating film 23 is substantially transparent to a visible light (400-800 nm) as shown by the curve “a”. This enables alignment of a glass mask accurately by detecting a mark reflective for the visible light and provided on the semiconductor substrate 11, for example. The alignment is performed using the visible light which is transmitted through the substrate 11. The glass mask has a pattern to be transferred, and is arranged closely to the surface of the resist film formed on the semiconductor substrate 11. As a result, positional error of the glass mask in plane (XY) and rotation directions can be corrected accurately. Since the alignment using visible light can be performed by a well-known alignment method, increase of the number of manufacturing steps is suppressed.

Then, as shown in FIG. 4D, by a sputtering method, a seed layer (not illustrated) containing titanium and copper, for example, is formed on a portion of the interlayer insulating films 15, a portion of the interconnection electrode 16 and the insulating film 23. These portions and insulating film form the penetration hole 21 respectively. Further, a resist film (not illustrated) for forming a plating pattern is formed. A conductor film 25 of copper, for example, is formed on the seed layer by an electrolytic plating method using the resist film as a mask. The conductor film 25 constitutes both a penetration electrode and an interconnection formed on a side of the lower surface (an upper side in FIG. 4D) of the semiconductor substrate 11.

Then, the above resist film is removed. A portion of the seed layer which does not contact the penetration electrode and the interconnection is further removed by a wet processing, for example. By removing the portion of the seed layer, a portion of the insulating film 23 is exposed.

As shown in FIG. 4E, a solder resist film 27 is formed on the conductor film 25 and the exposed portion of the insulating film 23, by an applying method. Further, as shown in FIG. 4F, an opening 27a is formed in a portion of the solder resist film 27 existing in an area by a photolithography method. In the area, a solder ball 31 shown in FIG. 2 is to be arranged.

As shown in FIG. 2, a solder ball 31 is arranged in the opening of solder resist film 27 to connect with the conductor film 25. Then, the wafer-shaped semiconductor substrate 11 is divided into pieces by a dicing method so that each solid state imaging device 5 is completed.

As shown in FIG. 1, a solid state imaging device 5 fixed to a glass substrate 43 is assembled to form one body together with a lens holder 53. A light filter 47 and an optical lens 51 are attached to the lens holder 53 so that a camera module 1 is obtained. In the camera module 1, side surfaces of the solid imaging device 5, the glass substrate 43 and the light filter 47 are covered by a shield 57.

In the camera module 1, a light which enters through the optical lens 51 from an object to be photographed is received by an imaging element portion 13 of FIG. 2. On the other, a light which proceeds to enter from the side surfaces is substantially intercepted by the shield 57.

The effect of intercepting an infrared light which proceeds to enter from the back surface of the semiconductor substrate 11 will be explained. The infrared light is intercepted in the solid state imaging device 5. The solid state imaging device 5 is incorporated in the camera module 1 and has the insulating film 23 which intercepts infrared ray.

As shown in FIG. 2, the solder ball 31 of the solid state imaging device 5 is connected to the electrode of the mount substrate 59. An incidence light 61 that is a sunlight enters into the solid state imaging device 5 through the space between the solder resist film 27 and the mount substrate 59. In a case that the mount substrate 59 is composed of a material capable of light transmission, an incidence light 61a going through the mount substrate 59 also enters into the solid state imaging device 5 from the back surface side.

The sunlight is a light which has a distribution in an ultraviolet area, a visible area and an infrared area. The semiconductor substrate 11 of silicon has a band gap wavelength of 1.11 μm, and has a characteristic easy to transmit an infrared ray adjacent to the visible area. The infrared light goes through the semiconductor substrate 11 of an about 100 μm thickness, reaches the imaging element portion 13, and becomes an obstructive light, i.e., a noise light to a light for imaging which enters from a direction of the object to be photographed.

Further, as shown by the curve “b” in FIG. 5, the semiconductor substrate of the about 100 μm thickness hardly causes an ultraviolet ray with a short wavelength to pass, and does not cause a visible light to pass substantially. When an infrared light having a wavelength exceeding 850 nm enters from the back surface of the semiconductor substrate 11, the infrared light reaches the imaging element portion 13 of the semiconductor substrate 11 and becomes a noise, at a high possibility.

On the other hand, the insulating film 23 for intercepting infrared ray contains the particles of the oxide such as the SnO₂—Sb₂O₃ series oxide or In₂O₃—SnO₂ series oxide coated with the insulating films 67, as shown in FIG. 3. The particles have a large transmission rate for visible light. The particles has a characteristic that the transmission rate of an infrared ray exceeding the wavelength of about 850 nm becomes 10% or less, as shown by the curve “a” in FIG. 5. In addition, as the wavelength of an incidence light becomes larger, the transmission rate of the light becomes smaller, as to the insulating film 23.

The insulating film 23 has a characteristic opposite to that of the semiconductor substrate 11 of the about 100 μm thickness. The transmission rate of incidence light of the semiconductor substrate 11 becomes larger gradually, when the wavelength of the light exceeds approximately 800 nm.

In FIG. 2, the incidence light 61 has a distribution in an ultraviolet area, a visible area and an infrared area. The incidence light 61 proceeds to enter from the back surface side of the semiconductor substrate 11. The incidence light 61 is intercepted by the insulating film 23 formed on the back surface side. Especially, an infrared light near the visible area is effectively suppressed to enter. In addition to a portion of the insulating film 23, a portion of the conductor film 25 is formed in the penetration hole 21 of semiconductor substrate 11. Thus, the incidence light 61 going to enter from the back surface side is intercepted more by the conductor film 25.

Since the insulating film 23 transmits a visible light, alignment of the semiconductor substrate 11 can be performed easily by the visible light in a subsequent manufacturing process of the solid state imaging device 5. Therefore, the positional accuracy of a pattern of the conductor film 25 can be ensured. As a result, the solid state imaging device 5 can be made without dropping manufacturing yield due to inaccurate alignment. Further, manufacturing of the solid state imaging device 5 is difficult to be influenced by an infrared light for alignment use which enters from the back-surface side of the semiconductor substrate 11. Accordingly, the device 5 presents a high performance.

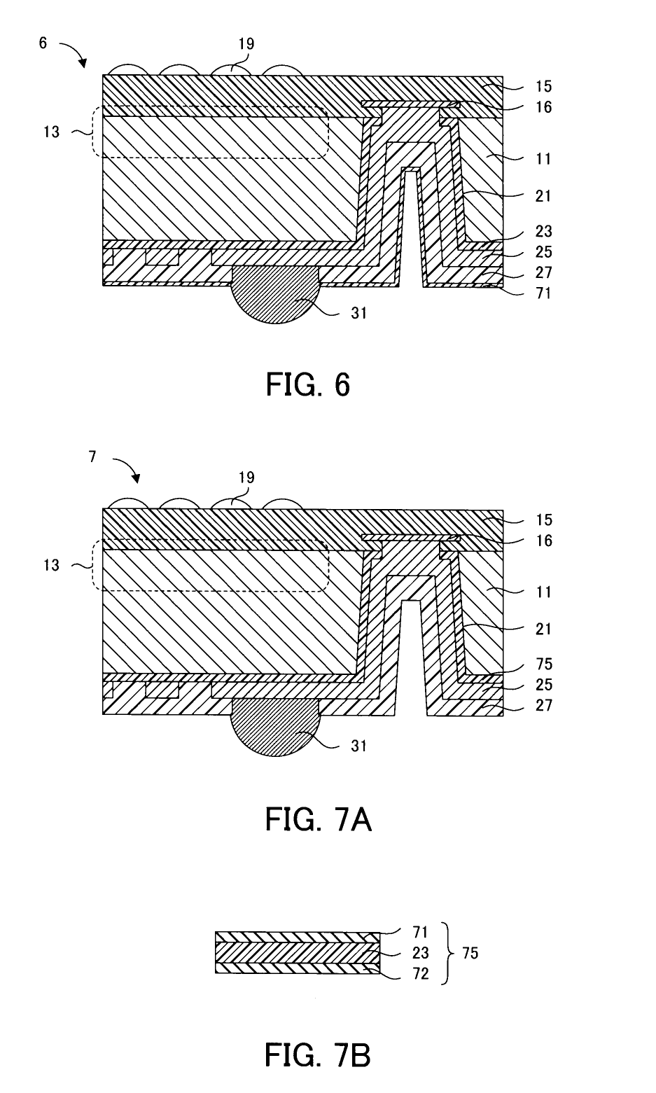

A solid state imaging device according to a modification of the first embodiment will be explained with reference to FIG. 6.

As shown in FIG. 6, in a solid state imaging device 6, a black-color insulating film 71 is thinly formed to be in contact with the surface of the solder resist film 27.

The solid imaging device 6 is manufactured by steps similar to those of the first embodiment until formation of the solder resist film 27 shown in FIG. 4E. Then, a black-color insulating film 71 is thinly formed on the undersurface of the solder resist film 27 by an applying method. The thickness of the black-color insulating film 71 to be obtained is a thickness to such a degree that alignment can be carried out by a visible light.

The black-color insulating film 71 may be a film made by causing polyimide to contain at least one of carbon particles, inorganic pigment particles or organic pigment particles. The transmission characteristic of the black insulating film 71 for a visible light depends on its thickness.

Further, openings are formed in the solder resist film 27 and in the black-color insulating film 71, by a photolithography method. A solder ball 31 is arranged in the openings, as shown in FIG. 6. Then, manufacturing steps similar to those of the first embodiment are employed, and the solid state imaging device 6 is completed.

As shown by the curve “c” in FIG. 5, when the black-color insulating film 71 is comparatively thick, the film 7 is capable of intercepting a visible light and an infrared light near the visible light. As shown by the curve “d” of FIG. 5, part of the visible light and the infrared light near visible light can be intercepted when the black-color insulating film 71 is made thin to such a degree that alignment can be carried out by visible light.

In the solid state imaging device 6, the black-color insulating film 71 is thinly formed on the undersurface side of the solder resist film 27. The solid state imaging device 6 may have the same effects as the solid state imaging device 5 of the first embodiment. In addition, the solid state imaging device 6 has an effect of intercepting the light 61 incidence to the back surface side more by adding the black-color insulating film 71.

A solid state imaging device according to a second embodiment will be explained with reference to FIG. 7A.

As shown in FIG. 7A, a solid state imaging device 7 has a structure which is obtained by replacing the insulating film 23 for intercepting infrared ray with an insulating film 75 for intercepting infrared ray. As shown in FIG. 7B, the insulating film 75 has a structure that insulating films 71 and 72 are laminated on the upper and lower surfaces of the insulating film 23. The laminated insulating films 71 and 72 may be a silicon oxide film or a silicon nitride film.

The solid imaging device 7 is manufactured by steps similar to those of the manufacturing method of the solid state imaging device of the first embodiment until formation of a penetration hole 21 shown in FIG. 4A. Then, as shown in FIG. 4B, an insulating film 71 is formed by a CVD (Chemical Vapor Deposition) method before forming an insulating film 23 for intercepting infrared ray. Subsequently, the insulating film 23 is formed on the insulating film 71 by an applying method, and further an insulating film 72 is formed on the insulating film 71 by a CVD method.

Then, the following manufacturing steps are employed. The manufacturing steps are similar to the step of FIG. 4D and those after the step of FIG. 4D respectively used in the manufacturing method of the solid state imaging device according to the first embodiment. As a result, the solid state imaging device 7 is completed. The insulating films 71 and 72 may be formed by using a SOG (Spin on Glass) method as the applying method. Only one of the insulating films 71 and 72 may be provided in the second embodiment.

Since the solid state imaging device 7 has the laminated structure of the insulating film 75, insulation of the insulating particles 65 is more effective. Especially, the insulation between the semiconductor substrate 11 and the conductor film 25 is enhanced.

Further, a black-color insulating film may be thinly formed on an outside of the solder resist film 27 of the solid state imaging device 7, like the modification of the first embodiment.

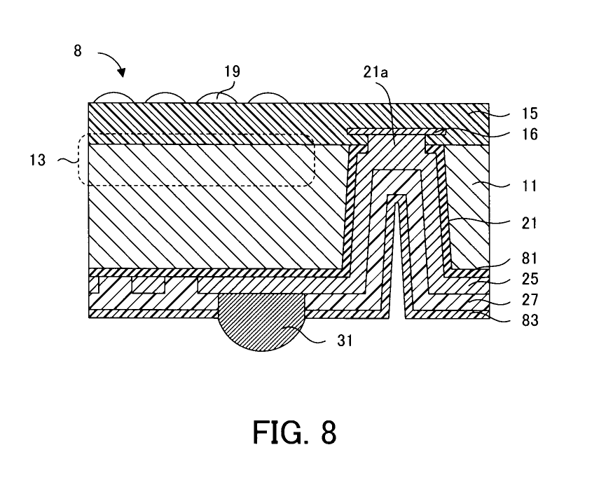

A solid state imaging device according to a third embodiment will be explained with reference to FIG. 8.

As shown in FIG. 8, a solid state imaging device 8 has a structure which is obtained by replacing the insulating film 23 for intercepting infrared ray with an insulating film 81 and by replacing the black-color insulating film 71 with an insulating film 83 similar to the insulating film 23 for intercepting infrared ray.

The solid imaging device 8 is manufactured by steps similar to those of the manufacturing method of the solid state imaging device according to the first embodiment until formation of a penetration hole 21 shown in FIG. 4A. Then, an insulating film 81 shown in FIG. 8 is formed by a CVD method. The insulating film 81 can be formed by using a SOG method as an applying method. Further, a conductor film 25 and a solder resist film 27 respectively shown in FIG. 8 are formed according to processes similar to those for forming respective films shown in FIGS. 4C to 4E.

Further, an insulating film 83 for intercepting infrared ray is formed on the undersurface side of the solder resist film 27 by an applying method. Then, by a photolithography method, openings are formed in the solder resist film 27 and in the insulating film 83 formed on the undersurface side of the film 27. A solder ball 31 is arranged in the openings. Subsequently, the following manufacturing steps are employed. The manufacturing steps are similar to the manufacturing method of the solid state imaging device according to the first embodiment. As a result, the solid state imaging device 8 is completed. Since the insulating film 83 is capable of transmit visible light as the insulating film 23 shown in FIG. 2 or 6, an alignment step can be performed easily.

Since, in the solid state imaging device 8, the insulating film 83 for intercepting infrared ray covers the whole surface of the solder resist film 27, the device 8 can present effects similar to those of the solid state imaging device 5 of the first embodiment.

A black-color insulating film may be thinly formed further on the undersurface side of the insulating film 83 that is the lowest layer of the solid state imaging device 8.

While certain-embodiments have been described, these embodiments have been presented by way of example only and are not intended to limit the scope of the inventions. Indeed, the novel devices described herein may be embodied in a variety of other forms; furthermore, various omissions and substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A solid state imaging device, comprising:
a semiconductor substrate which has first and second principal surfaces opposite to each other, the semiconductor substrate having a penetration hole extending from the first principal surface to the second principal surface;
an imaging element portion formed on the first principal surface side;
a first insulating film formed on the first principal surface side;
an interconnection electrode formed in the first insulating film and connected to the imaging element portion;
a second insulating film containing particles, being configured to intercept an infrared ray and to transmit a visible light, the second insulating film covering a surface of the penetration hole and the second principal surface except at least a portion of the interconnection electrode; and
a conductor film which contacts the interconnection electrode and is formed on the second insulating film, the conductor film being led out on a side of the second principal surface.

2. The solid state imaging device according to claim 1, further comprising an insulating protective film formed on the conductor film.

3. The solid state imaging device according to claim 1, further comprising a black-color insulating film configured to cover the insulating protective film.

4. The solid state imaging device according to claim 1, wherein the second insulating film has a structure that the particles are distributed in a resin.

5. The solid state imaging device according to claim 4, wherein each surface of the particles is covered with an insulating film.

6. The solid state imaging device according to claim 4, wherein the particles contain at least one selected from a SnO₂—Sb₂O₃ series oxide or an In₂O₃—SnO₂ series oxide.

7. The solid state imaging device according to claim 1, wherein the interconnection electrode is provided above the penetration hole.

8. The solid state imaging device according to claim 4, wherein the average diameter of the particles is 100 nm or less.

9. The solid state imaging device according to claim 4, wherein the average diameter of the particles is 10 to 50 nm.

10. The solid state imaging device according to claim 1, wherein the first insulating film has a concave hole between the penetration hole and the interconnection electrode, and, a portion of the conductor film is arranged in the concave hole.

11. The solid state imaging device according to claim 1, wherein, the second insulating film is arranged on at least one selected from an oxide film or a nitride film.

12. A solid state imaging device, comprising:
a semiconductor substrate which has first and second principal surfaces opposite to each other, the semiconductor substrate having a penetration hole extending from the first principal surface to the second principal surface;
an imaging element portion formed on the first principal surface side;
a first insulating film formed on the first principal surface side;
an interconnection electrode formed in the first insulating film and connected to the imaging element portion;
a second insulating film covering a surface of the penetration hole and the second principal surface except at least a portion of the interconnection electrode;
a conductor film which is formed to cover the second insulating film, to contact the interconnection electrode and to be led out on a side of the second principal surface; and
a third insulating film covering the conductor film and containing particles, being configured to intercept an infrared ray and to transmit a visible light.

13. The solid state imaging device according to claim 12, further comprising an insulating protective film formed between the conductor film and the third insulating film.

14. The solid state imaging device according to claim 12, further comprising a black-color insulating film configured to cover the third insulating film.

15. The solid state imaging device according to claim 12, wherein the third insulating film has a structure that the particles are distributed in a resin.

16. The solid state imaging device according to claim 15, wherein each surface of the particles is covered with an insulating film.

17. The solid state imaging device according to claim 15, wherein the particles contain at least one selected from a SnO₂—Sb₂O₃ series oxide or an In₂O₃—SnO₂ series oxide.

18. The solid state imaging device according to claim 12, wherein the interconnection electrode is provided above the penetration hole.

19. The solid state imaging device according to claim 15, wherein the average diameter of the particles is 100 nm or less.

20. The solid state imaging device according to claim 15, wherein the average diameter of the particles is 10 to 50 nm.
